(19) United States
(12) Patent Application Publication
(10) Pub. No.: US 2026/0159993 A1
(43) Pub. Date: Jun. 11, 2026

(54) FERROELECTRIC III-NITRIDE LAYER THICKNESS SCALING

(71) Applicant: The Regents of the University of Michigan, Ann Arbor, MI (US)

(72) Inventors: Ding Wang, Beijing (CN); Ping Wang, Beijing (CN); Zetian Mi, Ann Arbor, MI (US)

(21) Appl. No.: 19/150,123

(22) PCT Filed: Jan. 24, 2024
(86) PCT No.: PCT/US2024/012716

§ 371 Date: Jul. 22, 2025

Related U.S. Application Data
(60) Provisional application No. 63/440,900, filed on Jan. 24, 2023.

(51) Int. Cl. C30B 29/68; C01B 21/06; C30B 23/02; C30B 29/40; H10B 51/30; H10B 53/30; H10B 63/00; H10N 70/00; H10N 70/20

(52) U.S. Cl. CPC C30B 29/68; C01B 21/0602; C30B 23/025; C30B 29/403; H10B 51/30; H10B 53/30; H10B 63/30; H10N 70/25; H10N 70/8836; C01P 2002/72; C01P 2002/85; C01P 2004/04; C01P 2006/40

(57) ABSTRACT

A heterostructure includes a template layer and a ferroelectric semiconductor layer supported by the template layer, the ferroelectric semiconductor layer being single crystalline. The ferroelectric semiconductor layer includes an alloy of a III-nitride material. The alloy includes a Group IIIB element. The ferroelectric semiconductor layer is in contact with the template layer. The ferroelectric semiconductor layer has a thickness less than 100 nm.

### CROSS-REFERENCE TO RELATED APPLICATION

This application claims the benefit of U.S. provisional application entitled “Ferroelectric III-Nitride Layer Thickness Scaling,” filed Jan. 24, 2023, and assigned Ser. No. 63/440,900, the entire disclosure of which is hereby expressly incorporated by reference.

### STATEMENT REGARDING FEDERALLY SPONSORED RESEARCH OR DEVELOPMENT

This invention was made with government support under Contracts Nos. HR0011-22-2-0024 and HR0011-22-C-0087 awarded by the U.S. Department of Defense, Defense Advanced Research Projects Agency. The government has certain rights in the invention.

### BACKGROUND OF THE DISCLOSURE

### Field of the Disclosure The disclosure relates generally to Group III-nitride heterostructures.

### Brief Description of Related Technology

III-nitride (III-N) semiconductors exhibit wide and tunable direct bandgaps, large breakdown strength, high electron mobility, high electron saturation drift velocity, high thermal and chemical stability, and high radiation resistance, and have emerged as the enabling technology for a broad range of applications, from solid state lighting, radio-frequency (RF) and power electronics and to quantum information, renewable energy, as well as the emerging edge computing and artificial neuro networks. Due to the absence of spatial inversion symmetry in the wurtzite (wz) crystal structure of III-N semiconductors, a large spontaneous polarization nature is exhibited, which plays a useful role in reconfiguring the interface mobile charges to form two-dimensional electron/hole gases (2DEG/2DHG) and improving the quantum efficiency of light emitting diodes (LEDs).

Recently, ferroelectricity has been demonstrated in both sputtering deposited Sc-III-N and epitaxially grown Sc-III-N using molecular beam epitaxy (MBE). In such cases, the intrinsic spontaneous polarization of the nitride semiconductors can be reconfigured by an external electric field, thereby supporting applications in memories, transistors, resonators, filters, and other devices.

### SUMMARY OF THE DISCLOSURE

In accordance with one aspect of the disclosure, a heterostructure includes a template layer and a ferroelectric semiconductor layer supported by the template layer, the ferroelectric semiconductor layer being single-crystalline. The ferroelectric semiconductor layer includes an alloy of a III-nitride material. The alloy includes a Group IIIB element. The ferroelectric semiconductor layer is in contact with the template layer. The ferroelectric semiconductor layer has a thickness less than 100 nm.

In accordance with another aspect of the disclosure, a heterostructure includes a template layer, a ferroelectric semiconductor layer supported by the template layer, and a conductive layer adjacent to a side of the ferroelectric layer opposite the template layer. The ferroelectric semiconductor layer includes an alloy of a III-nitride material. The alloy includes a Group IIIB element. The ferroelectric semiconductor layer is in contact with the template layer. The side of the ferroelectric semiconductor layer has a native oxide layer with a thickness no greater than about 1 nm.

In accordance with still yet another aspect of the disclosure, a method of forming a heterostructure includes providing a template layer of the heterostructure, the template layer being supported by a substrate, implementing a surface treatment procedure to remove oxide from a surface of the template layer, after implementing the surface treatment procedure, implementing a non-sputtered, epitaxial growth procedure to form a ferroelectric semiconductor layer of the heterostructure, the ferroelectric semiconductor layer being supported by, and in contact with, the template layer, and depositing a conductive layer adjacent to a side of the ferroelectric layer opposite the template layer. The ferroelectric semiconductor layer includes an alloy of a III-nitride material. The non-sputtered, epitaxial growth procedure is configured to incorporate a group IIIB element into the alloy of the III-nitride material. Depositing the conductive layer is implemented such that exposure of the ferroelectric semiconductor layer to an ambient between the non-sputtered, epitaxial growth procedure and deposition of the conductive layer is limited to a time period such that a thickness of a native oxide layer disposed between the conductive layer and the ferroelectric semiconductor layer has a thickness no greater than about 1 nm.

In accordance with yet another aspect of the disclosure, a heterostructure includes a template layer and a ferroelectric semiconductor layer supported by the template layer, the ferroelectric semiconductor layer being single-crystalline. The ferroelectric semiconductor layer includes an alloy of a III-nitride material. The alloy includes a Group IIIB element. The ferroelectric semiconductor layer is in contact with the template layer. The ferroelectric semiconductor layer has a thickness less than 10 nm.

In accordance with yet another aspect of the disclosure, a heterostructure includes a template layer and a ferroelectric semiconductor layer supported by the template layer, the ferroelectric semiconductor layer being single-crystalline. The ferroelectric semiconductor layer includes an alloy of a III-nitride material. The alloy includes a Group IIIB element. The ferroelectric semiconductor layer has a thickness less than 100 nm. The ferroelectric semiconductor layer is in contact with the template layer such that a coercive field of the ferroelectric semiconductor layer is a function of a lattice mismatch between the template layer and the ferroelectric semiconductor layer.

In accordance with still yet another aspect of the disclosure, a method of forming a heterostructure includes providing a template layer of the heterostructure, the template layer being supported by a substrate, implementing a surface treatment procedure to remove oxide from a surface of the template layer, after implementing the surface treatment procedure, implementing a non-sputtered, epitaxial growth procedure to form a ferroelectric semiconductor layer of the heterostructure, the ferroelectric semiconductor layer being supported by, and in contact with, the template layer, and depositing a conductive layer adjacent to a side of the ferroelectric layer opposite the template layer. The ferroelectric semiconductor layer includes an alloy of a III-nitride material. The non-sputtered, epitaxial growth procedure is configured to incorporate a group IIIB element into the alloy of the III-nitride material. The conductive layer is deposited in situ such that the ferroelectric semiconductor layer is not exposed to an ambient between the non-sputtered, epitaxial growth procedure and deposition of the conductive layer.

In connection with any one of the aforementioned aspects, the devices and/or methods described herein may alternatively or additionally include or involve any combination of one or more of the following aspects or features. The heterostructure further includes a conductive, non-native passivation layer adjacent to a side of the ferroelectric layer opposite the template layer. An oxide layer is disposed between the conductive, non-native passivation layer and the ferroelectric semiconductor layer. The oxide layer has a thickness of about 1 nm or less. The conductive, non-native passivation layer includes a metal material. The metal material includes Al. The metal material includes Ti. The heterostructure further includes a non-native oxide layer adjacent to a side of the ferroelectric layer opposite the template layer. The non-native oxide layer includes indium tin oxide (ITO). The ferroelectric semiconductor layer has a thickness of about 30 nm or less. The ferroelectric semiconductor layer has a thickness of about 18 nm or less. The ferroelectric semiconductor layer has a thickness of about 10 nm or less. The ferroelectric semiconductor layer has a thickness of about 5 nm or less. The ferroelectric semiconductor layer has a wurtzite structure. A (0001) plane of the wurtzite structure is in contact the template layer. A surface of the template layer in contact with the single-crystalline semiconductor layer matches an atomic arrangement of the (0001) plane of the wurtzite structure. A surface of the template layer is oriented in the (011) plane. The template layer includes a metal. A surface of the template layer is oriented in the (111) plane. The Group IIIB element is scandium. The alloy of the III-nitride material includes AlN. The conductive layer includes a metal material. The conductive layer includes a non-native oxide layer. The ferroelectric semiconductor layer has a thickness of about 10 nm or less. The ambient includes a nitrogen-purged container. Depositing the conductive layer includes limiting the exposure to the ambient to less than about 24 hours. Depositing the conductive layer includes limiting the exposure to the ambient to less than about one hour. Depositing the conductive layer includes depositing a non-native oxide layer. Depositing the conductive layer includes depositing a metal layer. The non-sputtered, epitaxial growth procedure is configured such that the ferroelectric semiconductor layer has a thickness of about 10 nm or less. Implementing the surface treatment procedure includes annealing the template layer in a vacuum. The non-sputtered, epitaxial growth procedure is implemented under a nitrogen-rich condition.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts (a) a schematic of an ITO/ScAlN/Mo capacitor in accordance with one example, (b) RHEED patterns along the <112̅0> and <101̅0> azimuth for the 5 nm thick ScAlN layer, and (c) XRD 2θ/ω scans for ScAlN films grown on Mo template with various thicknesses (5-100 nm), in which the substrate is shown for comparison, and the peak at about 31.7° is from a Sc₂O₃ layer in the substrate.

FIG. 2 depicts (a) a cross-sectional HAADF-STEM image of an example 5 nm thick ScAlN layer grown on a Mo template, (b, c) nano-beam electron diffraction patterns captured from the Mo (b) and ScAlN (c) region labeled in (a), (d) a magnified HAADF-STEM image showing the thickness of the ScAlN layer, (e) a schematic view of the epitaxial relationship between wz-ScAlN and bcc-Mo, and (f) EDS element maps for an example ITO/ScAlN/Mo capacitor.

FIG. 3 depicts graphical plots of ferroelectric properties of example ScAlN films grown by MBE, including (a) C-V loops measured at an AC voltage of 200 mV and frequency of 2 MHz with a voltage step of 50 mV, (b) P-E loops measured using triangular waveform PUND measurements at 20 kHz, room temperature, (c) voltage-dependent PUND measurements using triangular pulses with a pulse width of 25 μs, in which butterfly-shape C-V loops are demonstrated in ScAlN films as thin as 5 nm, and saturated polarization in both bias directions is observed in 100 nm to 18 nm ScAlN, and in one bias direction for 12 nm and 5 nm thick examples, and in which the curves have been scaled to better show trending, and the nominal diameter of electrodes used was about 20 μm, which has been corrected by SEM.

FIG. 4 depicts graphical plots of comparisons of thickness-dependent (a) switchable polarization and (b) coercive field of a number of example ScAlN thin films, as well as data previously reported using sputter deposition by Fichtner and Schonweger et al. (cyan squares), Wang et al. (black square), Shinnosuke et al. (purple squares), Sushant et al. (green squares), Mizutani et al. (blue squares), and Ryoo et al. (magenta squares), in which error bars represent the standard deviation based on measurements from different example devices.

FIG. 5 depicts a cross-sectional, schematic view of a device having a heterostructure with an epitaxially grown single-crystalline III-nitride alloy layer in accordance with one example.

FIG. 6 is a flow diagram of a method of fabricating a heterostructure having an epitaxially grown single-crystalline III-nitride alloy layer in accordance with one example.

FIG. 7 depicts a cross-sectional, schematic view of a memory cell having a heterostructure with an epitaxially grown single-crystalline III-nitride alloy layer in accordance with one example.

FIG. 8 depicts a cross-sectional, schematic view of another transistor device having a heterostructure with an epitaxially grown single-crystalline III-nitride alloy layer in accordance with one example.

FIG. 9 depicts a cross-sectional, schematic view of a memory device having a heterostructure with an epitaxially grown single-crystalline III-nitride alloy layer in accordance with one example.

FIG. 10 depicts a cross-sectional, schematic view of a device having a freestanding heterostructure with an epitaxially grown single-crystalline III-nitride alloy layer in accordance with one example.

FIG. 11 depicts cross-sectional, schematic views of example heterostructures having epitaxially grown single-crystalline III-nitride alloy layers with and without a seeding layer, as well as graphical plots comparing electrical properties of the example heterostructures.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Heterostructures with a thin ferroelectric semiconductor layer are described. The thickness of the ferroelectric semiconductor layer may be scaled down to less than 100 nm, such as about 5 nm. The ferroelectric semiconductor layer may be composed of, or otherwise include, a III-nitride alloy, such as ScAlN. Methods for fabricating such heterostructures and devices are also described.

Ferroelectrics functioning at reduced dimensionality may be useful in constructing highly scaled, energy-efficient electronics and other devices. For instance, functioning at reduced dimensionality may lead to lower switching voltages and smaller domain size, both of which are useful for next-generation low power, high density and multifunctional devices and architectures, such as memory/sensing/computing devices. The presence of ferroelectric properties at scaled down sizes are accompanied by a number of processes involving domain wall motion and energy transfer, phase stability, strain, stoichiometry, and interface coupling, all of which are useful in understanding the fundamental and intrinsic properties of materials.

Sc alloyed III-nitride semiconductors have emerged as promising ferroelectrics with wide and tunable bandgap, large switchable polarization and high coercive field. The large switchable polarization provides more design freedom for field-charge coupling while the high coercive field provides a large memory window when integrated with field-effect transistors. Advancements in the deposition methods have opened the pathway to integrating Sc-III-N nitride ferroelectrics with mainstream semiconductors including silicon and GaN. However, the large switching voltages due to limited thickness scaling down have posed challenges on the practical applications of nitride ferroelectrics. On the other hand, unlike hafnia-based ferroelectrics, which tend to have competing phases, ferroelectric wurtzite phase is the energetically-stable crystalline phase in low-Sc-content Sc-III-N at room temperature, making it highly possible to maintain ferroelectric order in nitride ferroelectrics even at extremely reduced dimensionality. Therefore, the examples described herein usefully explore scaling down the thickness of nitride ferroelectrics.

The thickness scaling behavior of ScAlN formed by sputtering has been explored. The results have varied due to enhanced leakage current. In addition, polarization switching behavior has been characterized by non-saturated polarization with the thinnest layer limited to around 10 nm. For most conventional ferroelectrics, however, the thickness of the film needs to be scaled down to sub-10-nm regime to allow significant scaling behavior to be explored, which has remained challenging and elusive for nitride ferroelectrics.

Compared with sputter deposition, molecular beam epitaxy (MBE) and other non-sputtered epitaxial growth procedures provide better thickness and quality control, and are therefore useful for further extending the exploration of thickness scaling and behavior of nitride ferroelectrics.

Described below are example heterostructures that explore the ferroelectric switching behavior of ScAlN thin films in the thickness range of 100 nm to 5 nm grown by MBE. Reflection high energy electron diffraction (RHEED), X-ray diffraction (XRD) and scanning transmission electron microscopy (STEM) were used to characterize the wurtzite structure of the as-grown films. The ferroelectric properties of the as-grown films have been confirmed and investigated by capacitance-voltage (C-V) loops and positive-up-negative-down (PUND) measurements. Switching voltages approaching 2 V, and saturated remnant polarization of about 23 μC/cm² were demonstrated in an example having a 5 nm thick ScAlN layer. The disclosed devices and methods thus provide examples of the fundamental thickness-scaling properties of epitaxial ferroelectric ScAlN thin films, and of compact and power-efficient devices and applications based on nitride ferroelectrics.

The Sc content, thickness, and other characteristics of the wurtzite-phase ScAlN layers of the disclosed devices and methods may from the examples described herein. For instance, the Sc content, x, may vary from about 0.05 to about 0.5 in some cases. The Sc content may fall outside this range in other cases.

The disclosed devices and methods may include one or more elements, aspects, or other features described in International Application No. PCT/US2022/028365, filed May 9, 2022, and entitled “Epitaxial Nitride Ferroelectronics”), the entire disclosure of which is hereby incorporated by reference.

The ferroelectric semiconductor layer may be supported by, and in contact with, a metal template layer. For instance, the template layer may be composed of, or otherwise include, a CMOS compatible metal, such as molybdenum. The ferroelectric semiconductor layer may be single-crystalline or monocrystalline despite a polycrystalline nature of the metal layer. A surface of the metal layer may be oriented in a plane that matches the atomic arrangement of a wurtzite (0001) plane of the single-crystalline III-nitride alloy layer. The template layer may be composed of, or otherwise include, alternative or additional materials, including, for instance, GaN, silicon, and other semiconductor materials. The ferroelectric semiconductor layer supported by the template layer may be used in a variety of heterostructure arrangements and corresponding devices, including, for instance, capacitors and memristors (e.g., synaptic memristors), examples of which are described below.

The disclosed heterostructures, devices, and methods may integrate ferroelectric ScAlN and other III-nitride alloys with various metal materials. For instance, the metal materials may include metals compatible with complementary metal-oxide semiconductor (CMOS) circuits and fabrication processes. Such integration will apply the advantages of ferroelectric III-nitride materials (e.g., ScAlN) to enable applications from single devices to systems and even hybrid integrated circuits. For instance, making ferroelectric III-nitride materials compatible with CMOS and other technologies involves achieving single-crystalline ferroelectric ScAlN heterostructures on metal electrodes. Yet sputter deposited films are generally polycrystalline with very limited material quality.

The realization of fully epitaxial, single-crystalline ferroelectric III-N, e.g., ScAlN, on metal electrodes provides unique opportunities in bandgap/polarization engineering, interface/defects/doping control, thermal management, and high yield mass production. To date, however, the achievement of single-crystalline III-N semiconductors on metal has remained elusive, due to the severe lattice misalignment, highly reactive metallic surface, and lack of highly orientated metal substrate/template.

Among the commonly used CMOS compatible metals, the high melting point (about 2160° C.), low thermal expansion coefficient (5×10⁻⁶° C.⁻¹ at 20° C.), and low electrical resistivity (5×10⁻⁸ Ω·m) of molybdenum (Mo) make it a useful metal to withstand thermal budgets encountered in CMOS fabrication process. Additionally, Mo has a low acoustic attenuation due to the high acoustic velocity, and can also be easily wet etched. As such, Mo may be used as a bottom electrode for high frequency acoustic filters and resonators. Therefore, epitaxially grown III-N heterostructures on Mo may be used to achieve CMOS compatible ferroelectric nitrides and fully nitride-based complementary circuits, as well as a new class of integrable, ultralow loss, and ultrahigh frequency acoustoelectronic devices. This combination of III-N heterostructures on Mo also supports the integration of nonvolatile ferroelectric memristors (e.g., ScAlN memristors) with processors, which may be used, for instance, as a building block for rapid data transmission and analysis in artificial neural networks.

Although described in connection with examples of epitaxially grown ScAlN layers, the disclosed heterostructures, devices and methods may be applied to a wide variety of III-nitride alloys. The disclosed heterostructures, devices and methods may thus include or involve the incorporation of scandium into other III-nitride wurtzite structures. For instance, the disclosed heterostructures, devices and methods may include or involve one or more epitaxially grown ScAlGaN layers, ScAlInN layers, ScGaN layers, or ScInN layers. The configuration, construction, fabrication, and other characteristics of the heterostructures may also vary from the examples described. For instance, the heterostructures may include any number of epitaxially grown layers of ferroelectric and non-ferroelectric nature.

The disclosed heterostructures, devices and methods are also not limited to III-nitride alloys including scandium. For instance, the III-nitride alloys may include additional or alternative group IIIB elements, such as yttrium (Y) and lanthanum (La).

Although some aspects of the disclosed methods are described in connection with MBE growth procedures, additional or alternative non-sputtered epitaxial growth procedures may be used. For instance, metal-organic chemical vapor deposition (MOCVD) and hydride vapor phase epitaxy (HVPE) procedures may be used. Still other procedures may be used, including, for instance, pulsed laser deposition (PLD) procedures and atomic layer deposition (ALD) procedures.

Although described in connection with examples in which the III-nitride alloy is grown on a Mo layer, the disclosed heterostructures, devices and methods are not limited to growth on Mo layers. A variety of metals may be used, including, for instance, Al, Pt, Ti, Fe, Cu, and Ni. Although described in connection with polycrystalline metal layers, the disclosed heterostructures, devices and methods may alternatively or additionally include or use single-crystalline or monocrystalline metal layers.

III-N semiconductors with wz-phase (space group P6₃mc) lattices have the strongest polarization along the c-axis direction. Therefore, growing along <0001> direction maximizes the remnant polarization in ferroelectric nitrides. However, growth along alternative or additional directions may be implemented in other cases.

Described below are a number of examples grown using a Veeco GENxplor MBE system on Mo (011)/Sc₂O₃ (111)/Si (111) templates. The MBE system is equipped with a Vecco Unibulb radio frequency (RF) N-plasma source. Sc source (purity 99.999%) and Al source (purity 99.99995%) were provided utilizing a high-temperature Knudsen cell and a dual filament SUMO Knudsen cell, respectively. All of the ScAlN layers of the examples were grown under the same conditions, except for the growth duration. Further details regarding the growth conditions may be found in the above-reference patent publication.

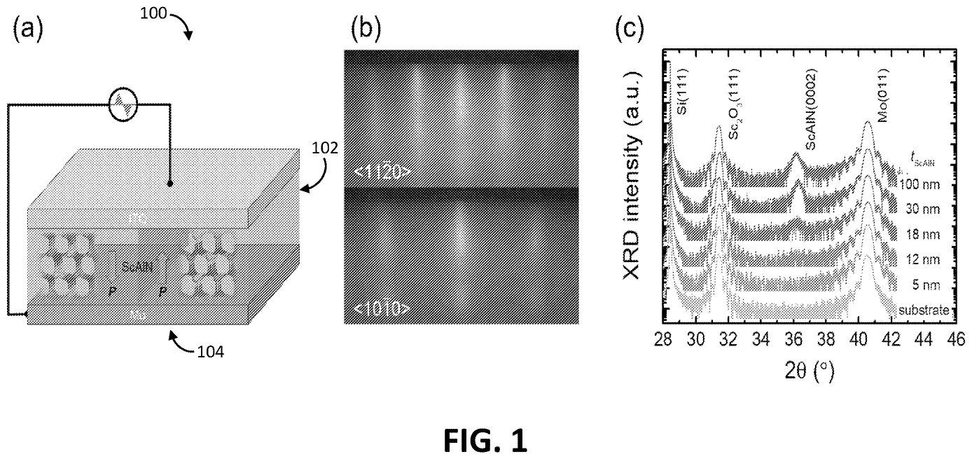

The thicknesses of the ScAlN films were varied from 100 nm to 5 nm, by changing the growth time, while the nominal Sc content was maintained at 0.3 to avoid secondary phase generation (although other content levels may be used in other cases). To eliminate the possible coupling of depletion region and substrate polarity pinning, ScAlN films were directly grown on metal substrates without GaN or AlN buffer. High temperature annealing was executed before ScAlN growth to obtain oxide-free Mo surface. The Sc content has been calibrated by energy dispersive X-ray (EDX) embedded in a scanning electron microscope (SEM) system. The growth process was in-situ monitored using a RHEED system. The crystal structures and film thicknesses were characterized by X-ray diffraction (XRD). To minimize the oxide layer formation after exposed to air, all ScAlN samples were quickly or immediately loaded into a sputter system (Lab 18) for 10-nm-ITO layer deposition after taking out from the MBE load-lock chamber. To fabricate the metal-ferroelectric-metal (MFM) capacitors, circular 100-nm-Au/50-nm-Ti/10-nm-ITO pads with a diameter of 10-50 μm were deposited on the ScAlN surface through a lithography process as the top electrodes, while the Mo template was used as the bottom electrode, illustrated in FIG. 1, part (a). To isolate the capacitors, residual ITO was etched away using HCl solution.

FIG. 1, part (a), shows a schematic of a device 100 in accordance with one example. In some cases, the device 100 includes a high quality wurtzite phase ferroelectric ScAlN layer 102 (e.g., a 100 nm thick layer) on a Mo(011) layer 104 with an epitaxial relationship of (0001)_{ScAlN}∥(011)_{Mo} and [112̅0]_{ScAlN}∥[10]_{Mo}. The thickness of the ScAlN layer 102 may vary as described herein.

FIG. 1, part (b), shows the RHEED patterns for an example having an ultrathin ScAlN with nominal thickness of 5 nm. A single set of wurtzite phase RHEED pattern was observed, indicating the absence of other phases or in-plane rotation. XRD 2θ/ω scans for all the ScAlN films were further shown in FIG. 1, part (c). For ScAlN films with a thickness larger than 18 nm, clear characteristic diffraction peaks for the (0002) plane of wurtzite ScAlN were observed at about 36°. Only a small shoulder at 36° is observed for 12-nm-thick ScAlN. The ScAlN signal is currently undetectable for the 5 nm thick ScAlN due to limitations of the measurement setup. The peak position here is slightly lower than previously reported on a GaN substrate, indicating that the ScAlN layers are under compressive stress. The peak at about 31.7° is from a Sc₂O₃ layer included in the substrate to support the characterization of the epitaxial relationship between the Si substrate and the Mo metal layer, and accordingly may not be present in examples of the disclosed heterostructures and devices.

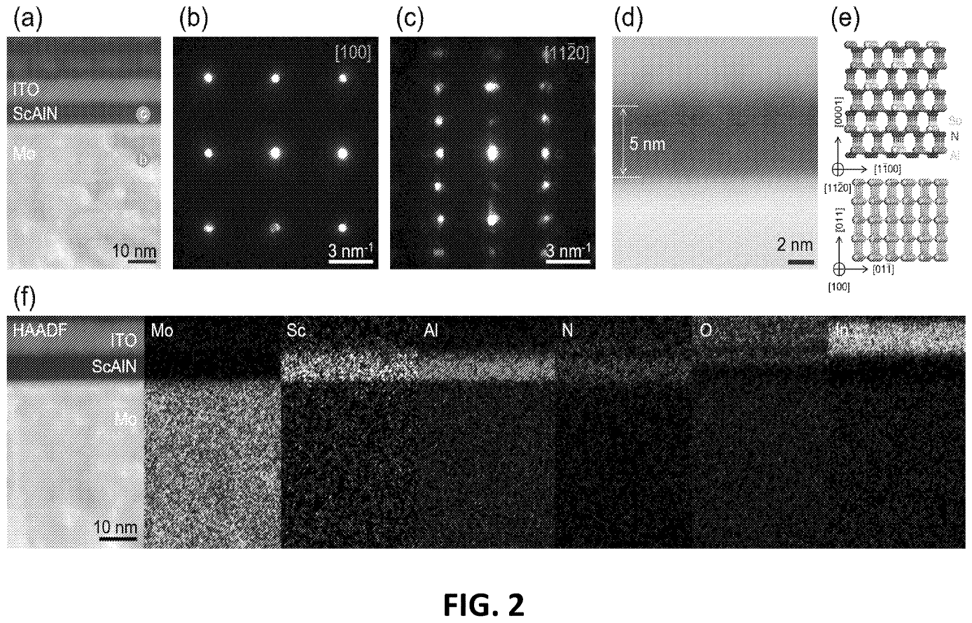

The crystal structure and thickness of the ultrathin (5 nm) ScAlN layer have been characterized using STEM measurements. FIG. 2, part (a), illustrates the cross-sectional high-angle annular dark field STEM (HAADF-STEM) image of the ScAlN grown on Mo(011), showing atomically sharp and clean ScAlN/Mo interface. FIG. 2, parts (b) and (c), presents the nano-beam electron diffraction (NBED) patterns recorded from the Mo and ScAlN layers, respectively, using the same electron beam azimuth. Electron diffraction pattern indicates that the ultrathin ScAlN grown on Mo has a single-phase wurtzite structure, as the reciprocal lattice spacing ratio between the (0002) and (11-20) plane reflections matches that for wurtzite crystal structure. The aligned manner of the electron diffraction patterns confirms the aforementioned epitaxial relationship between ScAlN and Mo, as sketched in FIG. 2, part (e). The thickness of 5 nm for the ScAlN layer was determined from the contrast variation (FIG. 2, part (d)). These results establish that uniform c-axis oriented wurtzite phase with the strongest polarization can be achieved in ultrathin ScAlN, which is useful for exploring the thickness scaling effect in ferroelectric ScAlN layers and devices.

A few nanometers (5-10 nm) thick native oxide layer can readily form on the ScAlN surface after exposure in air. With thickness scaling (e.g., down to sub-10-nm thicknesses), the effect of the native oxide on the ferroelectricity becomes more significant, which makes it challenging to achieve ferroelectric properties.

To eliminate or otherwise reduce the effect of the native oxide, a 10-nm-thick ITO layer is immediately or quickly deposited as a top electrode or other conductive layer after removal from the MBE chamber. The composition, thickness and other aspects of the deposited layer may vary in other cases. For instance, alternative or additional conductive layers (e.g., non-native passivation layers) may be used, including, for instance, other non-native oxides and metals, such as Al and Ti. The characteristics of the deposition procedure may also vary. For instance, the conductive, non-native passivation layer (or other conductive layer) may be deposited in any manner such that exposure of the ScAlN or other ferroelectric semiconductor layer to an ambient between the non-sputtered, epitaxial growth procedure and deposition of the conductive layer is limited to a time period such that a thickness of a native oxide layer disposed between the conductive layer and the ferroelectric semiconductor layer has a thickness no greater than about 1 nm. In some cases, the exposure to the ambient is limited to a time period less than 24 hours, or less than one hour. The ambient may or may not be air. For instance, the ambient may be established by, or otherwise include, a nitrogen-purged container.

In still other cases, the deposition of the conductive, non-native passivation layer or other conductive layer is implemented in situ such that the ferroelectric semiconductor layer is not exposed to the ambient between the growth and deposition procedures. For instance, the heterostructure may remain in the MBE growth chamber for the deposition of the conductive, layer. Formation of a native oxide on the ferroelectric semiconductor layer may accordingly be prevented.

FIG. 2, part (f), shows the EDS element maps of the example ITO/ScAlN/Mo capacitor. The maps indicate that Sc and Al were uniformly incorporated along the growth direction with a measured Sc content of about 0.3. An oxygen signal is observed in both the top surface of ScAlN and the ITO region. The oxide layer on top of ScAlN is determined to be about 1 nm by comparing the indium signal in the ITO region. This indicates that the native oxide layer commonly formed on the ScAlN surface was dramatically reduced to about 1 nm (from previously reports of thickness ranging from 5-10 nm) by reducing the exposure time in air. The formation of the ultrathin native oxide layer agrees with the observation of lattice degradation in FIG. 2, part (a). Except the 1 nm native oxide layer, the underlying 5 nm thick ScAlN layer possesses a well stacked wurtzite lattice without oxidation, enabling the exploration of ferroelectricity in such thin ScAlN. In other cases, the ITO layer may be replaced by in situ or ex situ deposition of other metal layers, such as Al, Ti, etc., which may further minimize or reduce oxidation.

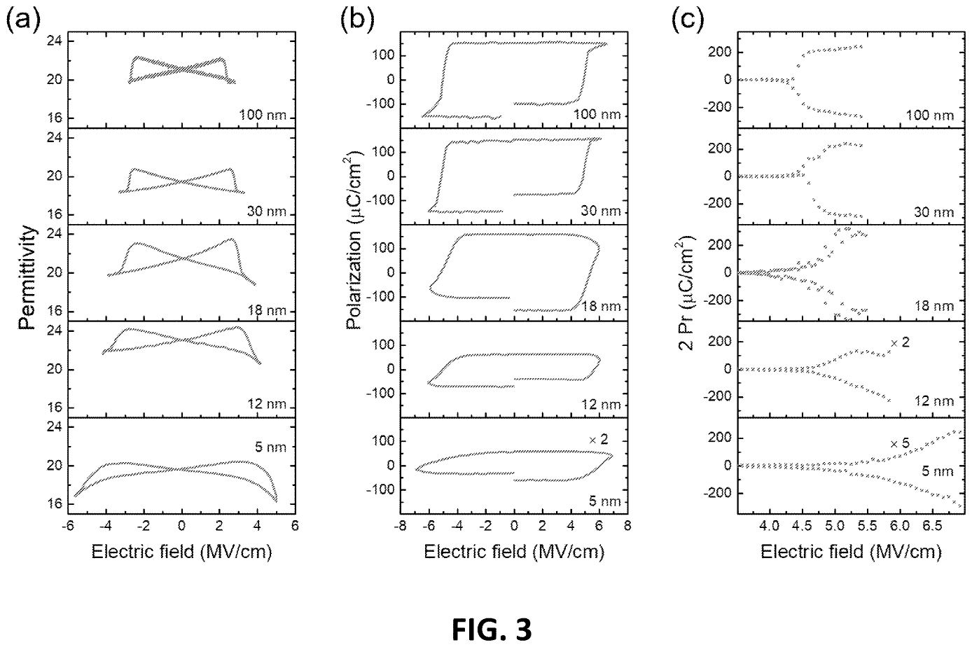

To examine the ferroelectric properties of the ScAlN thin films, C-V and P-E loops as well as PUND measurements were performed. FIG. 3, part (a), depicts the C-V loops measured for the example devices. Typical butterfly-shape C-V loops can be observed in each of the example devices, indicating the films are ferroelectric. For all measurements, the loss tangent, tan δ values were less than 0.1 at zero bias, which increased to less than 0.5 near the switching voltage due to increased leakage under high bias voltages. For leakage current compensation, a sequence of mono-polar triangular voltage pulses was applied to examine and subtract the non-switching current contribution. Saturated polarization in both bias directions can be observed for ScAlN films in the thickness range of 100 nm to 18 nm. For 12 nm and 5 nm thick ScAlN films, saturated polarization was observed in one bias direction, possibly due to enhanced leakage current in conjunction with asymmetric electrode configurations. To quantize the remnant polarization more precisely, voltage dependent PUND measurements using triangular pulses were performed and the results are displayed in FIG. 3, part (c). For ScAlN films above 12 nm, remnant polarization greater than 100 μC/cm² was detected. A spurring of the polarization values is present for the 18-nm thick sample, which may be due to growth or processing condition fluctuations. Saturated polarization was observed even for 12 nm and 5 nm thick ScAlN films at room temperature, in contrast with the non-saturated, partial polarization switching reported in around 10 nm ScAlN films deposited by sputtering, which is a strong indication of the improved film quality achieved by MBE. The switchable polarization decreased drastically from greater than 100 μC/cm² for thick films to about 50 μC/cm² for the 12 nm thick ScAlN example, and to about 23 μC/cm² for 5 nm thick ScAlN example, respectively. Meanwhile, the coercive field increases monotonously with decreasing film thickness, especially for the 5 nm thick example, which can also be seen in the C-V loops. By measuring multiple instances of each example device, the ratio between the breakdown field and coercive field, E_{BD}/E_{C}, was found to decrease slightly with thickness scaling down, from about 1.35 to about 1.22 when scaling from 100 nm to about 5 nm.

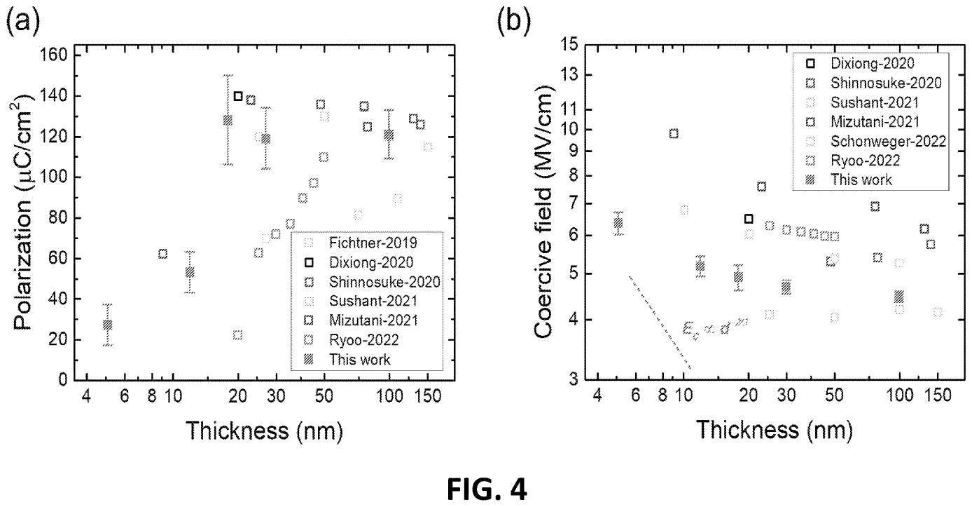

The switchable polarization and switching electric field are more clearly depicted in FIG. 4, parts (a) and (b). Results from previous studies were plotted together for comparison purposes. Overall, the coercive field increases monotonously with decreasing thickness, while the remnant polarization exhibits a significant diminishment upon scaling down to below 20 nm. The evolution of the ferroelectric properties is elucidated in the context of surface oxide and strain variation, as described below.

The driving force for the rising of coercive field upon thickness scaling down has been described by the classic Janovec-Kay-Dunn (JKD) model, where the coercive field of ferroelectrics scales linearly with d^{2/3}, with d being the ferroelectric film thickness, as indicated by the dotted line in FIG. 4, part (b). The deviation suggests the scaling behavior cannot be simply described by this domain nucleation based model. Depolarization field corrections based on the assumption of either a non-switchable dead layer or dielectric interfacial layer, or a finite screening length of the electrodes have been proposed to account for the sub-JKD scaling. In the examples described above, a thin oxide layer of about 1 nm is present on top of the ScAlN thin film. It is highly possible that the sub-JKD scaling behavior of the measured coercive field here is closely linked to the surface oxide layer. However, this cannot explain the drastic increase of the coercive field in the example having a 5 nm thick layer.

On the other hand, the ScAlN thin films are deposited on either Pt (111) or Mo (011) substrates, both of which have a smaller in-plane lattice constant compared with ScAlN. Therefore, compressive stress is expected to accumulate in the ScAlN layers, especially for epitaxially grown ultrathin films. The compressive stress, in conjunction with JKD scaling behavior, can give rise to a significantly increased coercive field. Using NEBD patterns, the in-plane and out-of-plane lattice constants of the 5 nm thick ScAlN with a Sc content of 0.3 are measured to be 3.198 Å and 5.068 Å, respectively. This in-plane lattice constant is even smaller than that of thick ScAlN films grown on Mo substrates with a Sc content of 0.2, indicating the existence of large compressive stress. Besides, the spontaneous polarization may tend to decrease with compressive stress in ScAlN alloys. Therefore, a slight decreasing trend of switchable polarization in wurtzite ScAlN upon thickness scaling down may occur considering enhanced compressive stress in the thinner ScAlN films grown on Mo. Therefore, it is concluded that the evolution of the coercive field and remnant polarization is a combined effect of surface oxide and compressive stress in the epilayers.

Nevertheless, the examples described above establish the possibility of achieving ferroelectric switching in nitride ferroelectrics as thin as about 5 nm. The switching voltage approaches 2 V according to C-V measurements, close to the silicon CMOS logic circuits standards (e.g., about 1.5 V), which is useful for power-efficient applications. The switchable polarization, although scaled down to about 23 μC/cm², is still comparable to most conventional ferroelectrics in similar thicknesses, and suitable for a variety of device applications.

Described above are examples that exhibit the thickness scaling behavior of ferroelectric Sc_{0.3}Al_{0.7}N films grown on Mo substrates by molecular beam epitaxy. Switchable ferroelectricity has been confirmed in ScAlN films with thicknesses ranging from 100 nm to 5 nm using C-V, P-E and PUND measurements. An increase in coercive field, and a significant diminution of remnant polarization, were found when the ferroelectric layer is scaled down to below 20 nm. Furthermore, a switching voltage of 2-3.8 V, and saturated remnant polarization of about 23 μC/cm² were obtained in examples having a 5 nm thick ScAlN layer, which is useful for scaled electronics. Thickness-scaling of MBE-grown ScAlN thin films may thus be used in compact and power-efficient devices and applications based on nitride ferroelectrics.

The disclosed heterostructures may be used in a variety of applications involving the heterogeneous integration of III-N architectures and CMOS technology. For instance, the nitride-based ferroelectrics of the disclosed heterostructures may be integrated in various other devices, systems, or applications, including a variety of advanced computing applications.

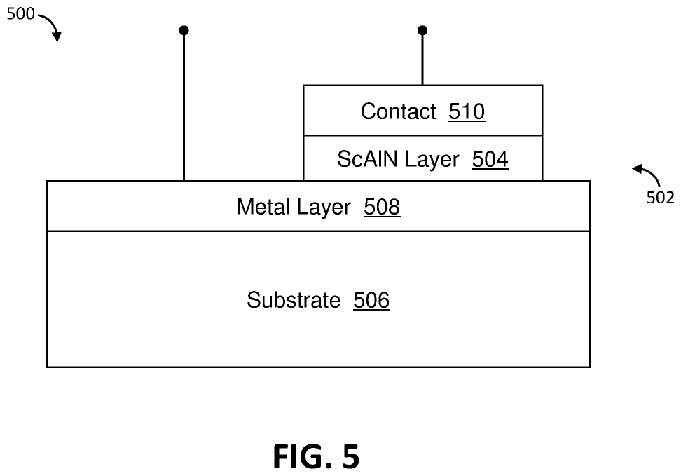

FIG. 5 depicts a device 500 having a heterostructure 502 with a ferroelectric semiconductor layer 504 in accordance with one example. The ferroelectric semiconductor layer 504 may have a thickness as described herein. In this example, the device 500 is a two-terminal device. In some cases, the device 500 is configured or operated as a capacitor. The device 500 may include any number of alternative or additional layers or structures. For instance, the device 500 may be integrated with any number of other devices.

The device 500 includes a substrate 506 and the heterostructure 502 supported by the substrate 506. The substrate 506 may be composed of, or otherwise include, silicon. Additional or alternative substrate materials may be used, including, for instance, sapphire, silicon carbide, bulk GaN, bulk AlN, GaN templates, and AlN templates. The substrate 506 may be uniform or composite.

The heterostructure 502 includes a template layer 508 and the ferroelectric semiconductor layer 504 supported by the template layer 508. The template layer 508 may be composed of a metal, such as molybdenum, or a semiconductor, such as GaN or silicon. As described herein, the ferroelectric semiconductor layer 504 is composed of, or otherwise includes, an alloy of a III-nitride material, such as ScAlN. In some cases, the ferroelectric semiconductor layer 504 may have a (0001) orientation. The orientation may vary in accordance with the epitaxial relationship between the template (e.g., metal) layer 508 and the ferroelectric semiconductor layer 504. The template (e.g., metal) layer 508 may be single-crystalline (or monocrystalline) or polycrystalline.

The alloy includes a Group IIIB element, such as Sc. The alloy may include one or more alternative or additional Group IIIB elements. In some cases, the III-nitride alloy is ScAlN. Alternative or additional III-nitride materials may be used, including, for instance, alloys of III-nitrides that include another group III element, such as Ga or In. Alternative or additional Group IIIB elements may be used, including, for instance, yttrium (Y) and lanthanum (La).

As shown in FIG. 5, the ferroelectric semiconductor layer 504 is in contact with the template layer 508 (e.g., metal layer). In this example, the surface of the metal layer 508 in contact with the ferroelectric semiconductor layer 504 is oxide-free. In some cases, the surface of the metal layer 508 in contact with the ferroelectric semiconductor layer 504 is oriented in the (011) plane. The plane in contact with the semiconductor layer 504 may vary in other cases, e.g., in accordance with the composition of the metal layer 508. For instance, with each metal material, the plane that matches (e.g., best matches) the atomic arrangement of the (0001) plane of the wurtzite structure may be used. In the example of FIG. 1, although the Mo (011) surface has a rectangular atomic arrangement, the rectangular atomic arrangement matches well with the hexagonal lattice of the III-N (0001) surface. The manner in which the planes match may thus vary with other atomic arrangements. For instance, the (111) plane may be in contact with the ferroelectric semiconductor layer 504 in heterostructures having an Al, Ni, or Cu layer in contact with the semiconductor layer. Other metal materials having the (011) plane matching the wurtzite structure may be used, including, for instance, Fe.

The template (e.g., metal) layer 508 may be composed of, or otherwise include, Mo. Additional or alternative metals may be used, as described above, including, for instance, Al, Ni, Cu, and Fe. In still other cases, the template layer 508 is composed of, or otherwise includes, a semiconductor material such as GaN or silicon. The material composition of the template layer 508 may establish a lattice mismatch between the template layer and the ferroelectric semiconductor layer. The lattice mismatch may, in turn, be used to tune or otherwise establish one or more properties or characteristics of the ferroelectric semiconductor layer 504. For instance, the coercive field of a ferroelectric nitride layer is a function of the lattice mismatch between the template layer 508 and the ferroelectric semiconductor layer 504. The coercive field can thus be modified (e.g., decreased or increased) in accordance with the amount or degree of lattice mismatch between the template layer 508 and the grown ferroelectric nitride layer 504.

The device 500 includes one or more electrodes or contacts 510. In this example, the heterostructure 502 further includes a top or upper contact 510 or other electrode in contact with the ferroelectric semiconductor layer 504. The contact 510 may be composed of, or otherwise include, the conductive, non-native passivation layer or other conductive layer as described herein. For example, the contact 510 may be composed of, or otherwise include, an ITO layer. The contact 510 may be additionally or alternatively composed of, or otherwise include, one or more metal layers, such as Ti and Al.

In the example of FIG. 5, the underlying metal layer 508 serves as a bottom or lower electrode. Additional or alternative contacts, electrodes or other structures may be included. In one capacitor example, 50-nm-Ti/100-nm-Au/50-nm-Ti circular pads with a diameter of 50 μm were lithographically patterned on the top surface of ScAlN as the top electrodes, while the bottom Mo layer was used as the bottom electrode. In other cases, to isolate each device, after the deposition of the top electrode, any uncovered portions of the semiconductor layer may be etched away, e.g., using a reactive ion etching (RIE) process

In the example of FIG. 5, the heterostructure 502 lacks a buffer layer between the ferroelectric semiconductor layer 504 and the metal layer 508. The device 500 thus provides an example of buffer-free direct epitaxial heterointegration between single-crystalline wurtzite phase ScAlN and a metal layer.

In this case, the metal layer 508 is in contact with the substrate 506. Alternatively, one or more layers or structures are disposed between the metal layer 508 and the substrate 506.

In some cases, the ferroelectric semiconductor layer 504 has an atomically smooth surface. The terms “atomically smooth” may be used herein in connection with layers of a heterostructure to indicate a layer having a surface roughness (e.g., a root mean square, or RMS, roughness) less than or on the order of 1 nm. In some cases, the RMS roughness of such atomically smooth layers is less than 1% of the thickness of the layer. The surface roughness may vary in accordance with the growth conditions, parameters, and other aspects of the fabrication processes described and/or referenced herein and/or other processes.

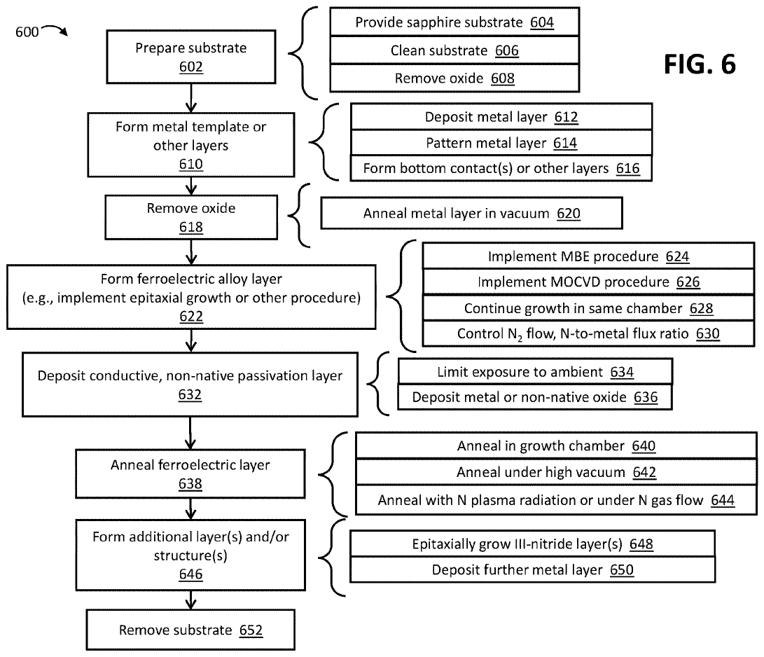

FIG. 6 depicts a method 600 of fabricating a heterostructure having a ferroelectric semiconductor layer (e.g., single crystalline wurtzite structure) of an alloy of a III-nitride material with scandium and/or another IIIB element incorporated therein in accordance with one example. As described herein, the method 600 is configured such that the ferroelectric semiconductor layer may be grown on a metal template, substrate, or other underlying layer. The heterostructure may form a device, or a part of a wide variety of devices that utilize the ferroelectric behavior. The method 600 may be used to fabricate the examples of ScAlN films and layers described herein or other ferroelectric semiconductor layers.

The method 600 may begin with an act 602 in which a substrate is prepared and/or otherwise provided. In some cases, the act 602 includes providing a silicon substrate in an act 604. The silicon substrate may have a (111) orientation. The substrate may be patterned or otherwise processed to configure the substrate to reduce defect formation in subsequently grown layers of the heterostructure and/or otherwise improve material quality therein. Such processing may also facilitate the formation of a different regions of the heterostructure.

Alternative or additional substrate materials may be used, including, for instance, sapphire, bulk GaN, bulk AlN, or other semiconductor material. Still other materials may be used, including, for instance, silicon carbide. In still other cases, a metal substrate may be used. For instance, the metal substrate may be composed of, or otherwise include, Al, Pt, and/or Mo.

The substrate may be cleaned in an act 606. In some cases, a native or other oxide layer may be removed from a substrate surface in an act 608. The oxide removal may include multiple steps, including, for instance, an etch step and an annealing step.

Additional or alternative processing may be implemented in other cases, including, for instance, doping or deposition procedures. The substrate thus may or may not have a uniform composition. The substrate may be a uniform or composite structure. Any number of layers or structures may be deposited on the substrate prior to the implementation of the acts described below.

The method 600 may include an act 610, in which one or more template or other layers (e.g., a seeding layer) are formed or otherwise provided. The template layer is supported by the substrate. In some cases, the template layer is in contact with the substrate. In other cases, one or more buffer or other layers or structures are disposed between the template layer and the substrate. As described herein, the template layer may be composed of, or otherwise include, a metal or a semiconductor material.

In the example of FIG. 6, the act 610 includes an act 612 in which the template (e.g., metal) layer(s) are deposited. A wide variety of deposition procedures may be used.

In some cases, the metal layer(s) are patterned in an act 614. Alternatively or additionally, the act 610 may include the formation of a seeding layer (e.g., via epitaxial growth). As described herein, the seeding layer may be composed of, or otherwise include, a III-nitride semiconductor, such as AlN or GaN.

The act 610 may include the deposition or other formation of one or more other metal layers or structures. For example, a bottom contact may be formed in an act 616. The act 616 may be implemented in parallel with (e.g., as part of) the act 612. The number and other characteristics of the metal layers or structures may vary in accordance with the configuration of the device (e.g., the number of terminals).

The method 600 includes an act 618 in which a surface treatment procedure is implemented to remove oxide from a surface of the metal layer of the template layer. In some cases, the act 618 includes annealing the polycrystalline metal layer in a vacuum in an act 620. The temperature of the annealing may vary, e.g., with the composition of the metal layer. For instance, MoO3 has a relatively low melting point (795° C.), in which case annealing above the melting point, e.g., at about 900° C., may be used. The annealing may also improve the surface roughness of the metal layer. In one example involving annealing at 900° C. for 10 minutes, except for the domain boundaries, a smooth surface was observed on each domain. To realize the above-described epitaxial relationship, the pre-annealing may be implemented in the MBE growth chamber to remove the native oxide (e.g., MoO₃) and obtain a fresh, clean, and atomically smooth Mo(011) surface. Furthermore, after the high-temperature annealing, the domain boundaries were more uniform with significantly reduced misoriented clusters. The oxide may be removed in additional or alternative ways to achieve a highly ordered atomically smooth surface. For instance, the oxide may be removed via an etching procedure using, e.g., an acid solution, such as hydrochloric acid (HCl) or buffered hydrofluoric acid (BHF).

In one example, a 120-nm-thick Mo layer was grown on a Si(111) substrate. The Mo template was cleaned by acetone, methanol, and deionized water prior to loading into the MBE system used for the growth of the single-crystalline semiconductor layer. The Mo templates were then degassed at 200 and 600° C. for 2 h in the MBE load-lock chamber and preparation chamber, respectively. In the growth chamber, the Mo template was annealed at 900° C. for 10 min before starting ScAlN growth, but the temperature and other parameters may vary in other cases (e.g., in connection with the composition).

After implementing the surface treatment procedure, a non-sputtered, epitaxial growth procedure is implemented in an act 622 to form a single-crystalline semiconductor layer supported by, and in contact with, the polycrystalline metal layer. As described above, the single-crystalline semiconductor layer is composed of, or otherwise includes, an alloy of a III-nitride material. The non-sputtered, epitaxial growth procedure is configured to incorporate a group IIIB element into the alloy of the III-nitride material.

The III-nitride alloy layer may or may not be ferroelectric. As described herein, the III-nitride alloy layer has a wurtzite structure. For instance, the III-nitride material may be AlN. Additional or alternative III-nitride materials may be used, including, for instance, gallium nitride (GaN), indium nitride (InN), and their alloys. As also described herein, the epitaxial growth procedure is configured to incorporate scandium and/or another group IIIB element into the alloy of the III-nitride material. The alloy may thus be ScAlN, for example. In some cases, the act 622 includes an act 624 in which an MBE procedure is implemented. In other cases, an MOCVD or other non-sputtered epitaxial growth procedure is implemented in an act 626.

The surface treatment of the act 618 may be implemented before (e.g., in preparation for) implementing the epitaxial growth procedure in which a wurtzite structure is formed. The wurtzite structure may thus be formed on the metal layer. The metal layer may thus act as a template for the wurtzite structure and/or other elements of the heterostructure. In some cases, the act 612 may include an act 628 in which the single-crystalline semiconductor layer is grown in a chamber in which the annealing procedure for the surface treatment of the act 618 is implemented. As a result, the substrate may remain within, e.g., is not removed from, the epitaxial growth chamber between forming the metal layer and growing the single-crystalline semiconductor layer.

The single-crystalline semiconductor layer may be grown on the metal layer using a wide growth window. For example, in some cases, the growth window may be similar to that for ScAlN grown on GaN, in which the low end of the growth temperature window is compatible with the CMOS fabrication process.

The growth temperature may be at a level such that the wurtzite structure exhibits a breakdown field strength greater than a ferroelectric coercive field strength of the wurtzite structure. Ferroelectric switching and other ferroelectric behavior may thus be achieved.

The growth temperature may be at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single-crystalline scandium-including alloy (e.g., a monocrystalline layer of the alloy) at the growth temperature level may nonetheless be achieved. For example, in some cases, a ScAlN alloy may be epitaxially grown at a growth temperature of about 650 degrees Celsius despite that the corresponding (scandium-free) III-nitride material, AlN, is conventionally grown at much higher temperatures, e.g., about 1000 degrees Celsius. Conversely, attempts to grow AlN at about 650 degrees Celsius or lower would result in structures of such poor quality. In contrast, the epitaxially grown ScAlN layer grown at that low temperature is unexpectedly of high quality and good electrical properties.

Growth of the ScAlN layer at the conventional AlN growth temperature (and other temperatures above the upper bound) unexpectedly results in the formation of dislocations and/or other leakage paths in the ScAlN layer. With the leakage paths, the ScAlN layer has a breakdown field strength level too low (e.g., below the ferroelectric coercive field strength level). The layer accordingly does not exhibit ferroelectric behavior.

In some cases, the growth temperature may be about 650 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range may vary in accordance with the alloy and/or the epitaxial growth technique. For instance, in other cases, the upper bound on the growth temperature may be higher, such as about 700 degrees Celsius, or about 750 degrees Celsius. In still other cases, the upper bound may be lower, including, for instance, about 550 degrees Celsius or about 600 degrees Celsius.

At each level within the above-described ranges of suitable growth temperatures, the resulting wurtzite structure is monocrystalline. The resulting wurtzite structure is monocrystalline to a degree not realizable via, for instance, sputtering-based procedures for forming ScAlN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

Additional or alternative differences in crystal quality may be used to distinguish between single-crystalline (or monocrystalline) and polycrystalline structures. As used herein, the term “polycrystalline” refers to structures having multiple domains with in-plane rotation. As used herein, the terms “monocrystalline” or “single crystalline” refer to structures having unique domains without in-plane rotation, e.g., as indicated by x-ray o scans that have only one set of diffraction peaks.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

In some cases, the wurtzite structure of the single-crystalline semiconductor layer is metal-polar. In other cases, the single-crystalline semiconductor may be nitrogen-polar (N-polar).

In some cases, the epitaxial growth procedure is implemented under a nitrogen-rich condition. For example, the nitrogen-to-metal flux ratio may be set in an act 630 in which the nitrogen flow is controlled. In some cases, the unbalanced flux ratio may be set to a highly or extremely nitrogen (N)-rich condition, such as a N-to-metal flux ratio of 2-to-1 or higher.

Control of the flux ratio between metal and nitrogen sources may be useful for improving the material quality of the ScAlN or other III-nitride alloy layer. As described herein, the N-rich growth conditions may be useful in connection with the growth of ScAlN to avoid Sc—Al intermetallic, Sc₃AlN perovskite phase formation, and/or other defects.

In one example, ScAlN films and GaN/ScAlN heterostructures were grown utilizing a Veeco GENxplor MBE system, equipped with dual filament SUMO Knudsen cells for Al (purity 6N5) and Ga sources (purity 7N), a high-temperature Knudsen cell for Sc source (purity 5N), and a Veeco Unibulb radio frequency (RF) plasma source. The N source was operated with a N₂ gas (purity 6N) flow of 0.35 sccm, and an RF power of 350 W corresponding to a growth rate of 240 nm/h was used for metal-rich GaN layers. To maintain the single wz-phase crystal structure for ScAlN, N-rich conditions were employed. While for the GaN/ScAlN heterostructures, the GaN was grown under metal-rich conditions and slightly doped with Si (electron concentration 1×10¹⁸ cm⁻³). The thickness for ScAlN and GaN were about 100 and 20 nm, respectively. The Sc content was around 20%.

The method 600 includes an act 632 in which a conductive layer (e.g., a conductive, non-native passivation layer) is deposited adjacent to a side of the ferroelectric layer opposite the metal layer. As described herein, the deposition of the conductive layer may be implemented such that exposure of the ferroelectric semiconductor layer to an ambient between the non-sputtered, epitaxial growth procedure and deposition of the conductive layer is limited to a time period such that a thickness of a native oxide layer disposed between the conductive layer and the ferroelectric semiconductor layer has a thickness no greater than about 1 nm. The act 632 may thus include an act 634 directed to limiting or preventing exposure to the ambient. In some cases, the act 634 may be configured to limit the time period during which the ferroelectric semiconductor layer is exposed to the ambient. For instance, the time period may be less than 24 hours, or less than one hour. Other time periods may be used. In other cases, exposure to the ambient may be prevented by depositing the conductive, non-native passivation layer (or other conductive layer) before removal from the chamber in which the ferroelectric semiconductor layer is grown.

The ambient may be controlled. For instance, in some cases, the ambient is established by, or otherwise includes, a nitrogen-purged container.

The act 632 may include deposition of a non-native oxide layer, such as ITO, in an act 636. Additional or alternative materials may be deposited, including, for instance, other non-native oxide materials and metals, such as Al and Ti.

In some cases, the single-crystalline semiconductor layer may then be annealed in an act 638. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Sc-III-N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of ScAlN may be performed in-situ in the same growth chamber (e.g., the same MBE chamber) in an act 640. In other cases, the annealing is performed ex-situ in a chamber directed to annealing procedures.

The annealing process may be implemented under high vacuum in an act 642 (e.g., in-situ in the growth chamber). In other cases, the annealing may be implemented either with nitrogen plasma radiation or under nitrogen gas flow in an act 644.

The above-described annealing procedure may be implemented in connection with films grown under any of the above-described growth conditions. For instance, the annealing procedure may be implemented after growth under slightly to moderately N-rich conditions at a growth temperature below about 650 degrees Celsius. The annealing procedure may also be implemented after growth under unbalanced flux ratios (e.g., N-rich or extreme N-rich conditions) at growth temperatures above about 650 degrees Celsius.

The method 600 may include an act 646 in which one or more layers (e.g., semiconductor layers) are formed after growth of the wurtzite structure. For instance, one or more III-nitride (e.g., GaN or AlGaN) or other semiconductor layers may be epitaxially grown in an act 648. The act 648 may be implemented in the same epitaxial growth chamber used to grow the wurtzite structure. As a result, the substrate (and heterostructure) is not removed from the epitaxial growth chamber between implementing the acts 622 and 648.

Alternatively or additionally, the act 640 includes an act 650 in which one or more metal or other conductive layers or structures are formed. For example, a metal layer may be deposited. The layers or structures may be deposited or otherwise formed. In some cases, the conductive structure is configured as an upper or top contact (or component thereof). For instance, the conductive structure may be a gate.

In some cases, the method 600 includes an act 652, in which the substrate is removed. The substrate may be partially or fully removed. With the substrate fully removed, the heterostructure becomes freestanding. In some cases, the act 652 includes implementation of an etching procedure, such as a wet or dry etch procedure. Alternatively or additionally, the substrate is removed mechanically. The manner in which the substrate is removed may thus vary accordingly.

The method 600 may include fewer, additional, or alternative acts. For example, one or more acts may be directed to forming other structures or regions of the device that includes the heterostructure. In a transistor device example, the regions may correspond with source and drain regions. The nature of the regions or structures may vary in accordance with the nature of the device. In another example, the method 600 does not include an act 610 in which a buffer layer is grown or otherwise formed.

The order of the acts of the method 600 may differ from the example shown in FIG. 6. For example, contacts and/or other structures formed in the act 610 may be implemented after the growth of the ferroelectric layer.

A number of different types of devices may be fabricated by the method 600 of FIG. 6, and/or another method of fabricating a heterostructure having a wurtzite structure of an alloy of a III-nitride material with scandium incorporated therein. For example, the ferroelectric ScAlN or other alloy of a III-nitride material may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers). Still other types of devices may be fabricated, including, for instance, FE-based thin-film bulk acoustic wave resonators (FBAR) devices.

The disclosed heterostructures may be incorporated into a wide variety of devices. In these cases, a conductive, non-native passivation layer (or other conductive layer) may be disposed on a side of a ferroelectric layer as described above and shown in, for instance, the example of FIG. 1. A number of examples are described below.

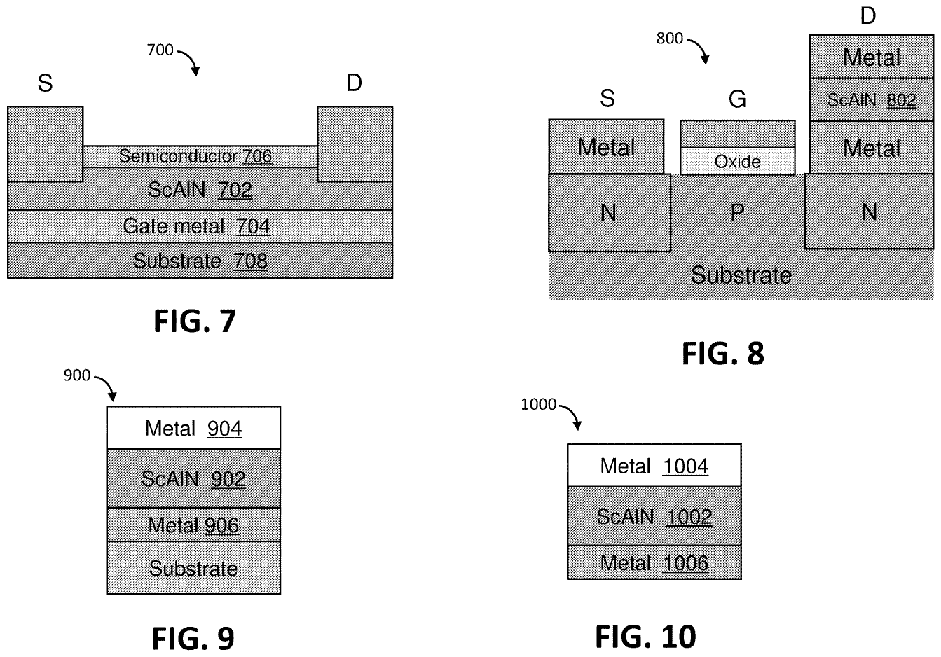

FIG. 7 depicts a FeFET memory device 700 in accordance with one example. A ferroelectric ScAlN layer 702 is disposed between a gate electrode 704 and a source-drain conduction region 706. The ferroelectric layer 702 provides a reversible electrical state for a transistor of the device 700. The large remnant electrical field polarization in the ferroelectric ScAlN layer 702 retains the state of the transistor (e.g., on or off) in the absence of any electrical bias to form a single transistor nonvolatile memory. In one example, bulk and/or other semiconductor channel layers are composed of, or otherwise include, GaN or silicon, or two-dimensional materials like MoS₂ or graphene. In each case, the FeFET memory device may include a heterostructure including, for instance, the ferroelectric ScₓAl₁₋ₓN or other alloy of a III-nitride material, along with one or more layers of a III-nitride semiconductor, such as AlN, as the gate dielectric and barrier. A substrate 708 supporting these layers and structures of the devices may be composed of, or otherwise include, for instance, GaN or silicon. The control terminal or gate 704 may be disposed below the III-nitride semiconductor layer 702 as shown. As described herein, the gate 704 may be composed of, or otherwise include, a metal, such as Mo.

FIG. 8 depicts a coupled FET structure 800 configured as a memory cell in accordance with one example. During the switching of the remnant polarization state in a ferroelectric (e.g., ScAlN) layer 802, a current pulse is generated to indicate the stored binary information in the cell.

FIG. 9 depicts an FTJ memory device 900 in accordance with one example. In this example, an epitaxially grown ferroelectric layer 902 (e.g., ScAlN layer) is disposed between metal layers 904, 906 (e.g., nickel and aluminum layers). The ScAlN or other alloy layer 902 provides the ferroelectricity and tunes the ON/OFF current/resistance ratio as a memorizer readout.

FIG. 10 depicts a device 1000 with a heterostructure in accordance with one example. The device 1000 may be configured or used as a filter, resonator, or other acoustic device. Such devices may be useful in broadband communication (e.g., 5G, 6G) contexts and other applications. In this example, the heterostructure of the device is freestanding. The heterostructure may be freestanding in the sense that a growth or other sacrificial substrate has been removed. The freestanding heterostructure may be subsequently mounted on, or supported by, another structure, such as a circuit board.

In the example of FIG. 10, the heterostructure includes a single-crystalline III-nitride alloy layer 1002 disposed between, and in contact with, two metal layers 1004, 1006. The composition, configuration, and other characteristics of the layers 1004, 1006 may vary as described herein. For instance, the metal layers 1004, 1006 may be composed of, or otherwise include, Ni, Al, Mo, or another metal. The metal layers 1004, 1006 may or may not be composed of, or include, the same metal material. In other examples, the single-crystalline III-nitride layer 1002 is in contact with only a single metal layer.

The heterostructures of the above-described devices may include any number of layers, structures, and/or components in accordance with the functionality of the device. For instance, the heterostructures may or may not include a seeding layer disposed between a metal layer and a single-crystalline III-nitride alloy layer.

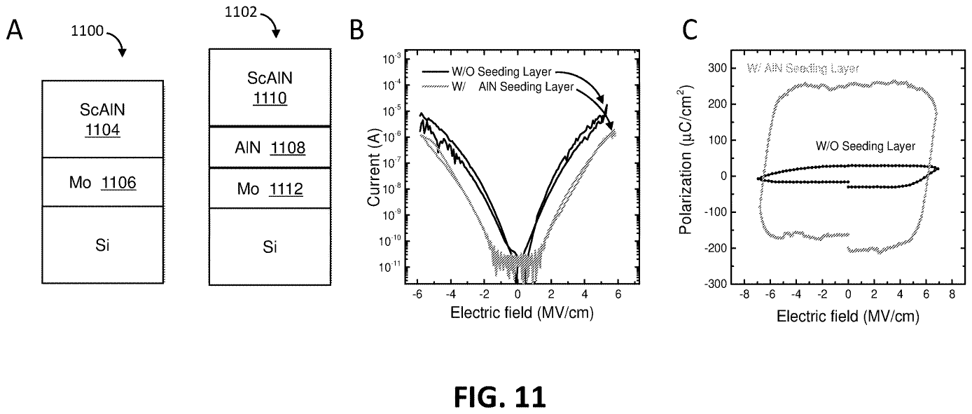

FIG. 11, part A, depicts a comparison of heterostructures 1100, 1102 with and without a seeding layer in accordance with two metal-insulator-metal capacitor examples. Each heterostructure 1100, 1102 is supported by a substrate, such as a silicon substrate. The heterostructure 1100 has a single-crystalline III-nitride alloy layer 1104 (e.g., an ultrathin ScAlN film as described herein) supported by, and in contact with, a metal template layer 1106 (e.g., a Mo layer). In contrast, the heterostructure 1102 has a seeding layer 1108 disposed between a single-crystalline III-nitride alloy layer 1110 and a metal layer 1112. The seeding layer 1108 and the metal layer 1112 may together establish a template (or template layer) for the III-nitride alloy layer 1110. In such cases, the template layer may be or include a combination of multiple layers, e.g., a composite layer or structure. Alternatively, the template layer is established by the seeding layer 1108 alone. In this example, the seeding layer 1108 is composed of, or otherwise includes, AlN. Additional or alternative materials may be used, including, for instance, other III-nitride materials.

The seeding layer 1108 may be configured to reduce the leakage current in the III-nitride alloy layer 1110. The effects of the seeding layer 1108 were investigated. In these two example heterostructures 1100, 1102, the III-nitride alloy layers 1104, 1110 have a thickness of about 6 nm. In the heterostructure 1110, the AlN seeding layer 1108 had a thickness of about 4 nm. Standard photolithography was used to fabricate the two capacitor heterostructures 1100, 1102 to characterize their electrical properties. As shown in FIG. 11, part B, the heterostructure 1102 with the seeding layer 1108, the leakage current was reduced by almost a factor of 10. Moreover, the switchable polarization, measured by the polarization-electric field loops, was also significantly improved, as shown in FIG. 11, part C. Those results exhibit a significant reduction in the leakage current, which may be useful in connection with a variety of nitride-based ferroelectric devices and device applications.

In other examples, a substrate other than a silicon substrate is used. For instance, the substrate may be composed of, or otherwise include, SiC or sapphire.

Described above are example heterostructures that illustrate, and make use of, thickness scaling behavior of ferroelectric ScAlN (e.g., SC_{0.3}Al_{0.7}N) films grown on Mo substrates by molecular beam epitaxy. Switchable ferroelectricity was confirmed in the example ScAlN films with thicknesses ranging from 100 nm to 5 nm. An increase in coercive field, and a significant diminution of remnant polarization were exhibited when the ferroelectric layer is scaled down to below 20 nm. Notably, a switching voltage of 2-3.8 V, and saturated remnant polarization of about 23 μC/cm² were measured in an example having a 5 nm thick ScAlN layer. X-ray diffractions and transmission electron microscopy indicated that the increase in coercive field and diminishment in switchable polarization are closely linked to the surface oxidation and strain state in ultrathin ScAlN films. The thickness-scaling characteristics of ScAlN thin films may be useful in a variety of devices based on nitride ferroelectrics, including compact and power-efficient devices and applications. Furthermore, the disclosed devices and methods may be useful in the integration of III-N architectures with various fabrication technologies, including, for instance, CMOS technologies, and may be useful in a number of applications, including, for instance, ferroelectric nitride memristors in neuromorphic computing.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A heterostructure comprising:
a template layer; and
a ferroelectric semiconductor layer supported by the template layer, the ferroelectric semiconductor layer being single-crystalline;
wherein:
the ferroelectric semiconductor layer comprises an alloy of a III-nitride material;
the alloy comprises a Group IIIB element;
the ferroelectric semiconductor layer is in contact with the template layer; and
the ferroelectric semiconductor layer has a thickness less than 100 nm.

2. The heterostructure of claim 1, further comprising a conductive, non-native passivation layer adjacent to a side of the ferroelectric layer opposite the template layer.

3. The heterostructure of claim 2, wherein:
an oxide layer is disposed between the conductive, non-native passivation layer and the ferroelectric semiconductor layer; and
the oxide layer has a thickness of about 1 nm or less.

4. The heterostructure of claim 2, wherein the conductive, non-native passivation layer comprises a metal material.

5. The heterostructure of claim 4, wherein the metal material comprises Al.

6. The heterostructure of claim 4, wherein the metal material comprises Ti.

7. The heterostructure of claim 1, further comprising a non-native oxide layer adjacent to a side of the ferroelectric layer opposite the template layer.

8. The heterostructure of claim 7, wherein the non-native oxide layer comprises indium tin oxide (ITO).

9. The heterostructure of claim 1, wherein the ferroelectric semiconductor layer has a thickness of about 30 nm or less.

10. The heterostructure of claim 1, wherein the ferroelectric semiconductor layer has a thickness of about 18 nm or less.

11. The heterostructure of claim 1, wherein the ferroelectric semiconductor layer has a thickness of about 10 nm or less.

12. The heterostructure of claim 1, wherein the ferroelectric semiconductor layer has a thickness of about 5 nm or less.

13. The heterostructure of claim 1, wherein:
the ferroelectric semiconductor layer has a wurtzite structure;
a (0001) plane of the wurtzite structure is in contact the template layer; and
a surface of the template layer in contact with the single-crystalline semiconductor layer matches an atomic arrangement of the (0001) plane of the wurtzite structure.

14. The heterostructure of claim 1, a surface of the template layer is oriented in the (011) plane.

15. The heterostructure of claim 1, wherein the template layer comprises a metal.

16. The heterostructure of claim 1, wherein a surface of the template layer is oriented in the (111) plane.

17. The heterostructure of claim 1, wherein the Group IIIB element is scandium.

18. The heterostructure of claim 1, wherein the alloy of the III-nitride material comprises AlN.

19. The heterostructure of claim 1, wherein the template layer comprises a III-nitride semiconductor layer.

20. A heterostructure comprising:
a template layer;
a ferroelectric semiconductor layer supported by the template layer; and
a conductive layer adjacent to a side of the ferroelectric layer opposite the template layer;
wherein:
the ferroelectric semiconductor layer comprises an alloy of a III-nitride material;
the alloy comprises a Group IIIB element;
the ferroelectric semiconductor layer is in contact with the template layer; and
the side of the ferroelectric semiconductor layer has a native oxide layer with a thickness no greater than about 1 nm.

21. The heterostructure of claim 20, wherein the conductive layer comprises a metal material.

22. The heterostructure of claim 20, wherein the conductive layer comprises a non-native oxide layer.

23. The heterostructure of claim 20, wherein the ferroelectric semiconductor layer has a thickness of about 10 nm or less.

24. A method of forming a heterostructure, the method comprising:
providing a template layer of the heterostructure, the template layer being supported by a substrate;
implementing a surface treatment procedure to remove oxide from a surface of the template layer;
after implementing the surface treatment procedure, implementing a non-sputtered, epitaxial growth procedure to form a ferroelectric semiconductor layer of the heterostructure, the ferroelectric semiconductor layer being supported by, and in contact with, the template layer; and
depositing a conductive layer adjacent to a side of the ferroelectric layer opposite the template layer;
wherein:
the ferroelectric semiconductor layer comprises an alloy of a III-nitride material;
the non-sputtered, epitaxial growth procedure is configured to incorporate a group IIIB element into the alloy of the III-nitride material; and
depositing the conductive layer is implemented such that exposure of the ferroelectric semiconductor layer to an ambient between the non-sputtered, epitaxial growth procedure and deposition of the conductive layer is limited to a time period such that a thickness of a native oxide layer disposed between the conductive layer and the ferroelectric semiconductor layer has a thickness no greater than about 1 nm.

25. The method of claim 24, wherein the ambient comprises a nitrogen-purged container.

26. The method of claim 24, wherein depositing the conductive layer comprises limiting the exposure to the ambient to less than about 24 hours.

27. The method of claim 24, wherein depositing the conductive layer comprises limiting the exposure to the ambient to less than about one hour.

28. The method of claim 24, wherein depositing the conductive layer comprises depositing a non-native oxide layer.

29. The method of claim 24, wherein depositing the conductive layer comprises depositing a metal layer.

30. The method of claim 24, wherein the non-sputtered, epitaxial growth procedure is configured such that the ferroelectric semiconductor layer has a thickness of about 10 nm or less.

31. The method of claim 24, wherein implementing the surface treatment procedure comprises annealing the template layer in a vacuum.

32. The method of claim 24, wherein the non-sputtered, epitaxial growth procedure is implemented under a nitrogen-rich condition.

33. The method of claim 24, wherein providing the template layer comprises growing a seeding layer.

34. A heterostructure comprising:
a template layer; and
a ferroelectric semiconductor layer supported by the template layer, the ferroelectric semiconductor layer being single-crystalline;
wherein:
the ferroelectric semiconductor layer comprises an alloy of a III-nitride material;
the alloy comprises a Group IIIB element;
the ferroelectric semiconductor layer is in contact with the template layer; and
the ferroelectric semiconductor layer has a thickness less than 10 nm.

35. A heterostructure comprising:
a template layer; and
a ferroelectric semiconductor layer supported by the template layer, the ferroelectric semiconductor layer being single-crystalline;
wherein:
the ferroelectric semiconductor layer comprises an alloy of a III-nitride material;
the alloy comprises a Group IIIB element;
the ferroelectric semiconductor layer has a thickness less than 100 nm; and
the ferroelectric semiconductor layer is in contact with the template layer such that a coercive field of the ferroelectric semiconductor layer is a function of a lattice mismatch between the template layer and the ferroelectric semiconductor layer.

36. A method of forming a heterostructure, the method comprising:
providing a template layer of the heterostructure, the template layer being supported by a substrate;
implementing a surface treatment procedure to remove oxide from a surface of the template layer;
after implementing the surface treatment procedure, implementing a non-sputtered, epitaxial growth procedure to form a ferroelectric semiconductor layer of the heterostructure, the ferroelectric semiconductor layer being supported by, and in contact with, the template layer; and
depositing a conductive layer adjacent to a side of the ferroelectric layer opposite the template layer;
wherein:
the ferroelectric semiconductor layer comprises an alloy of a III-nitride material;
the non-sputtered, epitaxial growth procedure is configured to incorporate a group IIIB element into the alloy of the III-nitride material; and
the conductive layer is deposited in situ such that the ferroelectric semiconductor layer is not exposed to an ambient between the non-sputtered, epitaxial growth procedure and deposition of the conductive layer.
